(19) United States
(12) Patent Application Publication
(10) Pub. No.: US 2010/0226193 A1
(43) Pub. Date: Sep. 9, 2010

(54) SEMICONDUCTOR MEMORY DEVICE

(75) Inventors: Hideaki Yamauchi, Fuchu-shi (JP); Hiroaki Nakano, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/633,238

(22) Filed: Dec. 8, 2009

(30) Foreign Application Priority Data
Mar. 6, 2009 (JP) 2009-053720

(51) Int. Cl. G11C 17/18; H01L 29/86

(52) U.S. Cl. 365/225.7; 257/529; 257/E29.325

(57) ABSTRACT

A unit memory circuit includes a fuse element capable of electrically programming data. A sense amplifier circuit is connected to the fuse element. The sense amplifier circuit senses data of the fuse element. Either of a first interconnect and a second interconnect is selectively formed by changing an interconnect formation mask. The first interconnect is short-circuiting the fuse element and the second interconnect is cutting off a current path when data is read from the fuse element.

### CROSS-REFERENCE TO RELATED APPLICATIONS

This application is based upon and claims the benefit of priority from prior Japanese Patent Application No. 2009-053720, filed Mar. 6, 2009, the entire contents of which are incorporated herein by reference.

### BACKGROUND OF THE INVENTION

1. Field of the Invention

The present invention relates to a semiconductor memory device including a ROM configured using an electrically programmable fuse element.

2. Description of the Related Art

A mask ROM has been known as a semiconductor memory device used for the purpose of storing program data for controlling the operation of a one-chip microcomputer. In the mask ROM, if there is a need to change data in the chip development initial stage, a mask must be remade. For this reason, there is a problem that long development time is spent. In order to solve the foregoing problem, it is expected to provide an electrically programmable fuse element, which has no generation of feedback to mask correction even if there is a need to correct data in a test stage.

However, a semiconductor memory device using the foregoing fuse element has the following problem. Specifically, if there is a need to write the same data in each chip at mass production stage, a program operation must be performed so that data is set to each chip. For this reason, time is taken to produce a program. In addition, the fuse element has the following problem that data is set one time only according to a program operation.

Japanese Patent Application KOKAI Publication No. 4-206099 discloses the following mask ROM. The mask ROM can electrically changes the logic of an output circuit of a circuit externally in the final production state to invert output data.

### BRIEF SUMMARY OF THE INVENTION

According to a first aspect of the present invention, there is provided a semiconductor memory device comprising:
a fuse element capable of electrically programming data;
a sense amplifier circuit connected to the fuse element to sense data of the fuse element; and
either of a first interconnect selectively formed by changing an interconnect formation mask, and short-circuiting the fuse element and a second interconnect cutting off a current path when data is read from the fuse element.

According to a second aspect of the present invention, there is provided a semiconductor memory device comprising:
a fuse element capable of electrically programming data;
a sense amplifier circuit connected to the fuse element to sense data programmed in the fuse element;
a latch circuit connected to the sense amplifier circuit, and including an inversion function of holding a sense output of the sense amplifier circuit; and
either of a first interconnect selectively formed by changing an interconnect formation mask and outputting the sense output of the sense amplifier circuit as read data and a second interconnect outputting an output of the latch circuit as read data.

According to a third aspect of the present invention, there is provided a semiconductor memory device comprising:
a first area including a plurality of first unit memory circuits, each of the first unit memory circuit comprising: a first fuse element capable of electrically programming data; and a first sense amplifier circuit connected to the first fuse element and sensing data programmed in the first fuse element; and
a second area including a plurality of second unit memory circuits, each of the second unit memory circuit comprising: a second fuse element capable of electrically programming data; a second sense amplifier circuit connected to the second fuse element and sensing data programmed in the second fuse element; and either of first and second interconnects selectively formed by changing an interconnect formation mask and setting memory data regardless of a program state of the second fuse element.

### BRIEF DESCRIPTION OF THE SEVERAL VIEWS OF THE DRAWING

FIG. 1 is a block diagram schematically showing the configuration of a semiconductor memory device according various embodiments of the present invention;

FIG. 2 is a flowchart to explain development and a mass production process of the semiconductor memory device show in FIG. 1;

FIGS. 3A to 3D are a circuit diagram showing one configuration example of a unit memory circuit used for a field program area of FIG. 1, and circuit diagrams to explain a program operation and a data read operation;

FIGS. 4A to 4C are a circuit diagram showing another configuration example of a unit memory circuit used for a field program area of FIG. 1, and circuit diagrams to explain a program operation and a data read operation;

FIGS. 5A and 5B are circuit diagrams showing the configuration of a unit memory circuit used for a semiconductor memory device according to a first embodiment;

FIGS. 6A and 6B are circuit diagrams showing the configuration of a unit memory circuit used for a semiconductor memory device according to a second embodiment;

FIGS. 7A and 7B are circuit diagrams showing the configuration of a unit memory circuit used for a semiconductor memory device according to a third embodiment; and

FIGS. 8A and 8B are circuit diagrams showing the configuration of a unit memory circuit used for a semiconductor memory device according to a fourth embodiment.

### DETAILED DESCRIPTION OF THE INVENTION

Recently, an electrical process of applying voltage or current stress to a MOS semiconductor element and an interconnect layer is employed to change the electric characteristic of devices. An element storing information using the foregoing process is used as a memory element (hereinafter, referred to as an e-fuse). In this way, the e-fuse is used, and thereby, a nonvolatile memory device capable of writing data one time only is developed.

For example, in a MOS device, a gate oxide film is formed between a gate electrode and a source/drain so that they are insulated. A high voltage is applied to the gate oxide film so that dielectric breakdown is generated, and thereby, a conducted state is provided. The foregoing electrical process is employed, and thereby, a state that gate electrode and the source/drain are insulated is set to “0” while a state that they are conducted is set to “1”. In this way, the MOS device is usable as a memory device.

Moreover, a polysilicon layer used for the gate electrode has usually low resistance. However, for example, when current stress is applied to the polysilicon layer, electromigration occurs, and thereby, the polysilicon layer is set to a high-resistance state. Therefore, a low-resistance state is set to “0” while a high-resistance state is set to “1”, and thereby, the MOS device is usable as a memory device. In this specification, the foregoing device is generally called as an e-fuse.

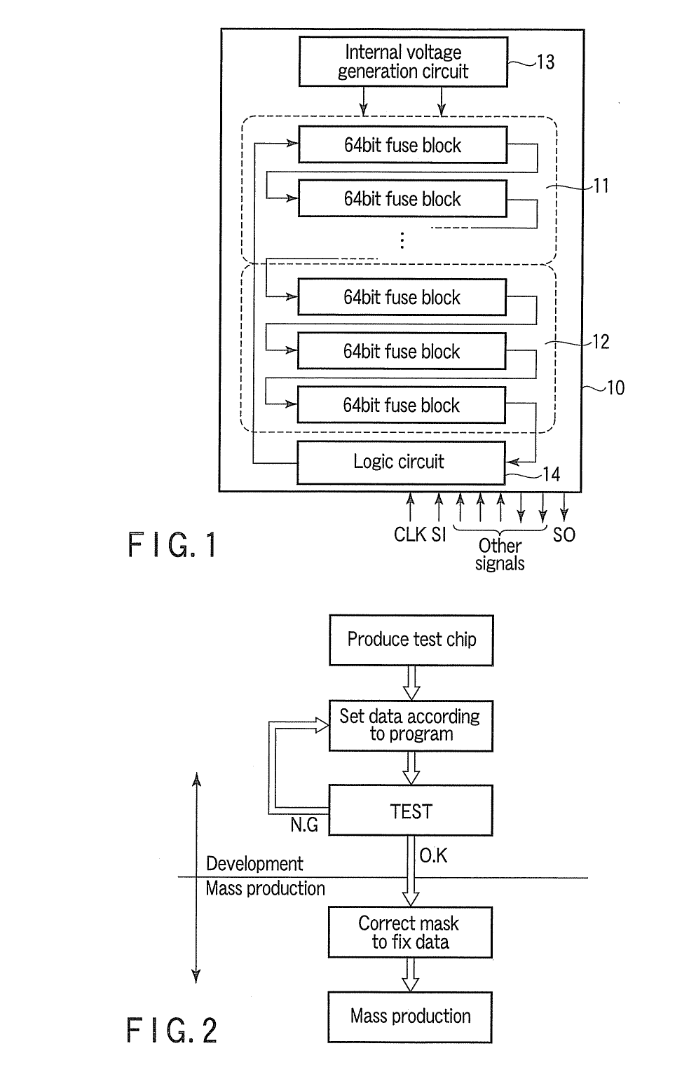

FIG. 1 is a block diagram schematically showing the configuration of a semiconductor memory device according various embodiments of the present invention. A semiconductor memory device 10 shown in FIG. 1 is macronized in such a manner that a plurality of e-fuses is integrated. According to fuse-macro shown in FIG. 1, a plurality of 64-bit e-fuse blocks each including 64 unit memory circuits are integrated. Each e-fuse block includes serial-connected 64 unit memory circuits and its control circuit. For example, each unit memory circuit includes an e-fuse, a select transistor for selecting the e-fuse, a sense amplifier circuit for reading data stored in the e-fuse and a data register for holding data read from the sense amplifier circuit. Further, a plurality of the e-fuse blocks is connected in serial at several stages, and thereby, large-capacity fuse macro is realized. A part of a memory area is used as a field program area 11 while other memory area is used as a ROM area 12. Further, the semiconductor memory device 10 includes an internal voltage generation circuit 13 and a logic circuit 14 in addition to a plurality of e-fuse blocks. Specifically, the internal voltage generation circuit 13 generates a plurality of internal voltages required for program and sense operations. The logic circuit 14 controls a fuse-macro operation. The logic circuit 14 synchronizes with a clock signal CLK to serially input program data from a data input terminal SI, and serially reads data from a data output terminal SO in a data read operation. Further, the logic circuit 14 inputs and outputs other various control signals to perform controls for program to the e-fuse and data sense read.

The semiconductor memory device 10 is integrated in a semiconductor chip such as a one-chip microcomputer, and used for the purpose of storing microcomputer operation control program data. Chip inherent data such as a chip ID and circuit trimming information are set to the field program area 11 according to a program operation after chip production. The ROM area 12 is the same circuit configuration as the field program area 11, and used as an area for setting data identical to all chips such as microcomputer program data. Therefore, the ROM area 12 is an area provided as a ROM in such a manner that interconnects of the unit memory circuit, that is, interconnect formation mask is corrected (e.g., one-layer mask is corrected) in mass production. Thus, data is previously set to the ROM area 12 in production. FIG. 1 shows the case where the semiconductor memory device comprises the field program area 11 and the ROM area 12. In this case, the semiconductor memory device may be configured using the ROM area 12 only.

For example, the semiconductor memory device shown in FIG. 1 is developed and mass-produced using a process shown in the flowchart shown in FIG. 2. Specifically, in the development stage, a great many of test chips is formed on a semiconductor wafer (production of test chip). Data is set to each unit memory circuit included in the ROM area 12 according to a program operation (set data according to program). Thereafter, programmed data is evaluated (TEST). If the data is not correctly programmed (NG), data is again programmed to another chip or wafer, and then, evaluated. If it is confirmed that the data is correctly programmed (OK), the process flow proceeds to a mass production stage. In the mass production stage, if there is a need to set the same data as each chip, time is taken in the case of using the foregoing process that data is set according to the program operation of the semiconductor memory device. For this reason, although detailedly described later, layout data is corrected to produce a mass-production mask (correct mask to fix data). Interconnects are formed in each unit memory circuit included in the ROM area 12 using the foregoing corrected mask; in this way, data is set. Thereafter, chips are mass-produced.

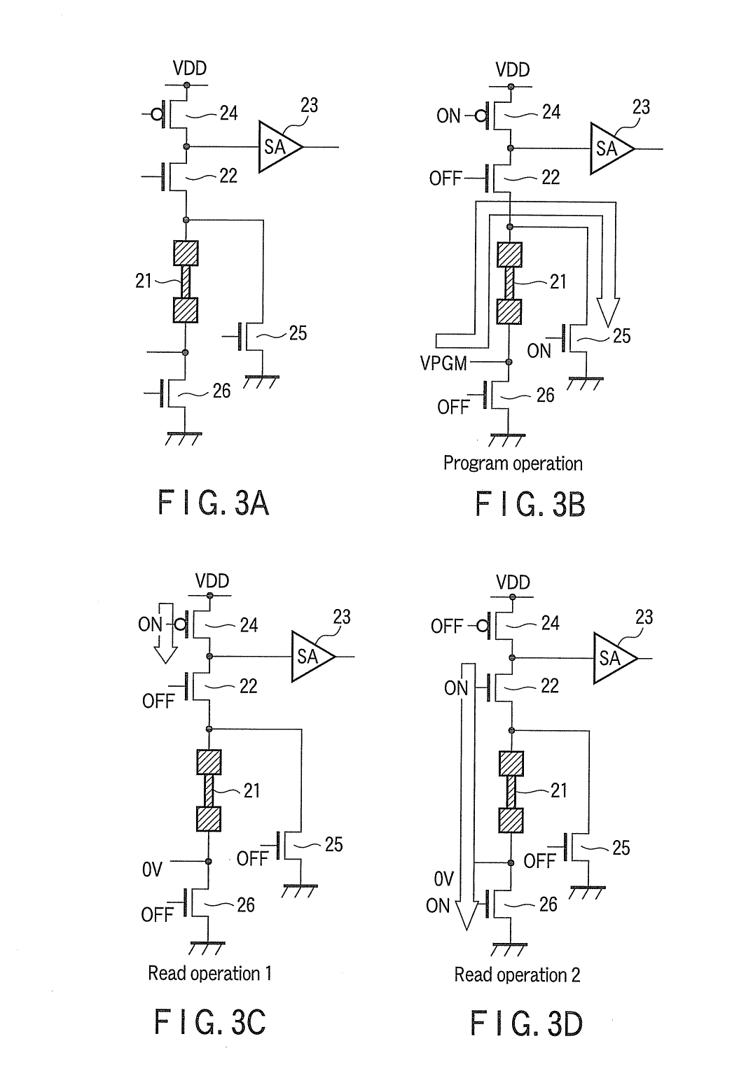

FIGS. 3A to 3D are circuit diagrams showing one configuration example of each of unit memory circuits used for the semiconductor memory device 10 shown in FIG. 1. FIG. 3A is a circuit diagram showing the configuration of a unit memory circuit. FIG. 3B is a circuit diagram to explain a program operation, and FIGS. 3C and 3D are circuit diagrams to explain a data read operation. As can be seen from FIG. 3A, each unit memory circuit is provided with a fuse element 21 such that data is electrically programmed. According to this embodiment, the following gate layer of a transistor is used as the fuse element 21. The gate layer is in a conducted state before program, and fused by carrying a current in a program operation to obtain a high-resistance state. One terminal of the fuse element 21 is connected with an input node (sense node) of a sense amplifier circuit (SA) 23 for sensing data of the fuse element 21 via an NMOS transistor 22 functioning as a switch. A PMOS transistor 24 is connected between the input node of the sense amplifier circuit 23 and a power supply voltage VDD node. The PMOS transistor 24 functions as a switch for pre-charging the input node of the sense amplifier circuit 23 when the data of the fuse element 21 is sensed. Further, an NMOS transistor 25 functioning as a switch in a program operation is connected between the other terminal of the fuse element 21 and a ground voltage node. Further, an NMOS transistor 26 functioning as a switch in a read operation is connected between one terminal of the fuse element 21 and a ground voltage node. In FIGS. 3A to 3D, a data register for holding data read by the sense amplifier circuit 23 is omitted in illustration.

As shown in FIG. 3B, transistors 22 and 26 are turned off, the transistor 25 is turned on, and a program voltage VPGM is applied to the other terminal of the fuse element 21. In this way, a program operation of the unit memory circuit shown in FIG. 3A is made. According to the foregoing operation, a current shown by the arrow in FIG. 3B flows through the fuse element 21 so that the fuse element 21 is broken down and set to a high-resistance state; in this way, data is written.

A read operation is performed in the following manner. Specifically, as shown in FIG. 3C, the transistor 24 is turned on in a state that transistors 22, 25 and 26 are turned off, and thereby, the input node of the sense amplifier circuit 23 is pre-charged. A VPGM terminal is set to 0 V. As can be seen from FIG. 3D, transistors 22 and 26 are turned on in a state that transistors 24 and 25 are turned off. If the fuse element 21 is not broken down, a read current shown by the arrow in FIG. 3D flows through the fuse element 21, and then, the input node of the previously pre-charged sense amplifier circuit 23 is discharged to the ground voltage node. Conversely, if the fuse element 21 is broken down in the program operation, no current flows through the fuse element 21; therefore, the input node of the sense amplifier circuit 23 is not discharged. The foregoing operation is carried out, and thereby, the voltage (potential) of the input node of the sense amplifier circuit 23 is different in accordance with the program state of the fuse element 21. The voltage is amplified by the sense amplifier circuit 23, and thereafter, read as data.

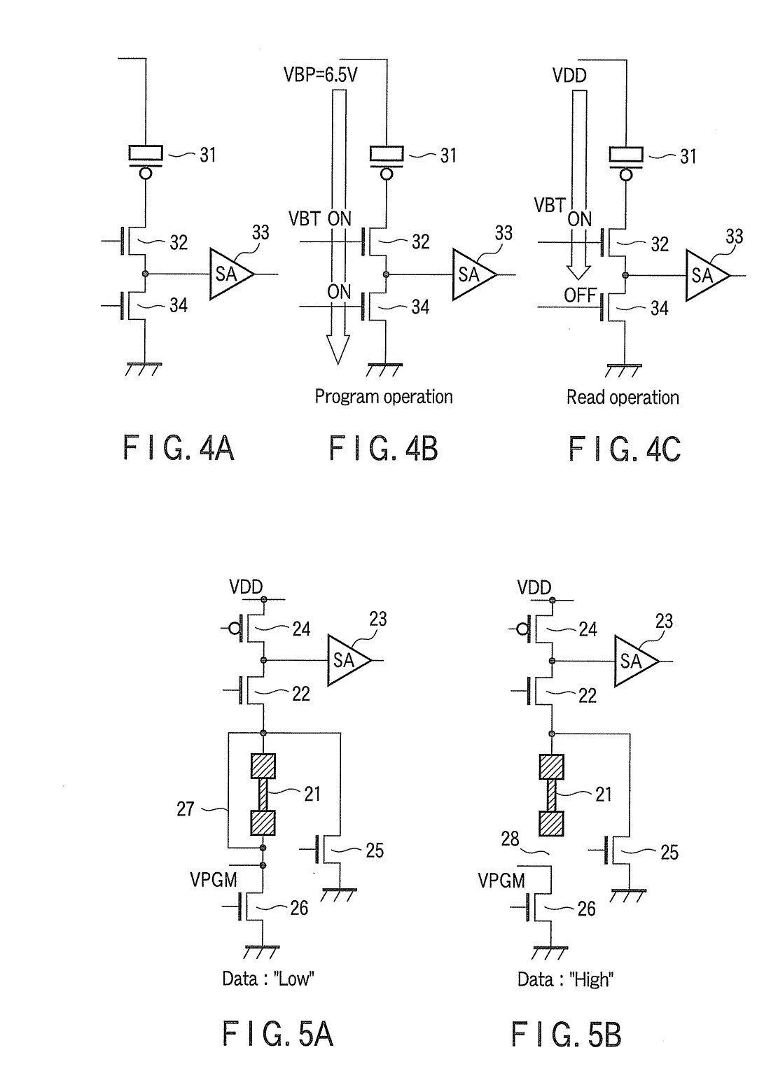

FIGS. 4A to 4C are circuit diagrams showing another configuration example of each of unit memory circuits used for the semiconductor memory device 10 shown in FIG. 1. FIG. 4A is a circuit diagram showing the configuration of a unit memory circuit. FIG. 4B is a circuit diagram to explain a program operation, and FIG. 4C is a circuit diagrams to explain a data read operation. As can be seen from FIG. 4A, each unit memory circuit is provided with an anti-fuse element 31 such that data is electrically programmed. According to this embodiment, a PMOS transistor is used as the anti-fuse element 31. VBP terminal of the anti-fuse element 31 is connected with a source/drain/substrate of the PMOS transistor; while the other terminal thereof is connected with a gate terminal of the PMOS transistor. The foregoing connection is made, and thereby, the PMOS transistor (anti-fuse element 31) is in a non-conducted state before program. A high electric field is applied to the MOS transistor (anti-fuse element 31) in a program operation, and thereby, a gate oxide film is broken down so that a conducted state is provided. Therefore, the PMOS transistor is usable as a so-called anti-fuse element. The gate terminal of the anti-fuse element 31 is connected with an input node (sense node) of a sense amplifier circuit (SA) 33 for sensing data held in the anti-fuse element 31 via an NMOS transistor 32. In this case, the NMOS transistor 32 functions as a barrier for preventing a program high voltage (VBP) from being directly applied to the sense amplifier circuit 33 and an NMOS transistor 34 described later in a program operation. The NMOS transistor 34 functioning as a switch is connected between the input node of the sense amplifier circuit 33 and a ground voltage node. The purpose of using the barrier transistor 32 is to protect elements of the unit memory circuit from a program voltage VBP. For this reason, a voltage (VBT) of two to three times as much as VDD is applied to the gate terminal of the barrier transistor 32. In FIGS. 4A to 4C, a data register for holding data read by the sense amplifier circuit 33 is omitted in illustration.

As shown in FIG. 4B, a program operation of the unit memory circuit show in FIG. 4A is carried out in the following manner. Specifically, transistors 32 and 34 are turned on, and the other terminal of the anti-fuse element 31 is supplied with a program voltage VBP enough to break down the gate oxide film of the anti-fuse element 31 for predetermined time. According to the foregoing state, a large electric field is applied to the gate oxide film of the anti-use element 31, and thereby, the oxide film is broken down. In this way, both terminals of the anti-fuse element 31 are conducted; therefore, the anti-fuse element 31 becomes a low-resistance state. In the manner described above, a state data is written in the anti-fuse element is provided.

As shown in FIG. 4C, a read operation is carried out in a state of applying a voltage such as power supply voltage VDD to the VBP terminal and discharging the input node of the sense amplifier circuit 33 to VSS. The gate of transistor 32 is supplied with a voltage VBT so that the transistor 32 is turned on, and the transistor 34 is turned off. If the oxide film of the anti-fuse element 31 is broken down in a program operation, a read current shown by the arrow in FIG. 4C flows through the anti-fuse element 31, and then, the input node of the sense amplifier circuit 33 is set to a voltage such as power supply voltage VDD. Conversely, if the oxide film of the anti-fuse element 31 is not broken down, the foregoing current shown by the arrow in FIG. 4C does not flow through the anti-fuse element 31. By the foregoing operation, the voltage of the input node of the sense amplifier circuit 33 is different in accordance with a program state of the anti-fuse element 31. The voltage is amplified by the sense amplifier circuit 33, and thus, read as data.

In the manner described above, each unit memory circuit is programmed, and data is read.

### First Embodiment

FIGS. 5A and 5B show a semiconductor memory device according to a first embodiment of the present invention. That is, FIGS. 5A and 5B are circuit diagrams showing one configuration example of each unit memory circuit located in the ROM area 12 shown in FIG. 1. In each unit memory circuit, a polysilicon fuse element, which is fused by carrying a current, is used as an e-fuse like each unit memory circuit shown in FIG. 3A. The unit memory circuit includes a fuse element 21, an NMOS transistor 22, a sense amplifier circuit (SA) 23, a PMOS transistor 24, NMOS transistors 25 and 26, like the circuit shown in FIG. 3A.

If there is a need to set the same data in each chip, in the semiconductor memory device of this embodiment, the fuse element 21 of each unit memory circuit is not electrically programmed, but data is set using the following process. Specifically, as can be seen from the foregoing flowchart shown in FIG. 2, layout data of an interconnect formation mask is corrected based on data to be stored in the mass-production stage. Either of the following interconnects is selectively formed using the foregoing corrected mask. One is an interconnect short-circuiting the fuse element 21. The other is an interconnect cutting off a current path when data is read from the fuse element 21.

For example, as can be seen from FIG. 5A, a unit memory circuit configured to store low data is formed with an interconnect 27, which short-circuits both terminals of the fuse element 21. Even if the interconnect 27 does not exist, data is intactly “L”. However, the foregoing state is programmable; for this reason, there is the possibility that data is written in error. But, according to this embodiment, the fuse element is short-circuited using the foregoing interconnect. Therefore, it is possible to obtain the effect of preventing the foregoing write error without breaking down the fuse element by a current. As shown in FIG. 5B, a unit memory circuit storing high data is formed with an interconnect 28 such that a current path between the fuse element 21 and the transistor 26 is cut off (opened).

In the unit memory circuit shown in FIG. 5A, the fuse element 21 is always short-circuited by the interconnect 27. The input node of the sense amplifier circuit 23 is pre-charged by the transistor 24, and thereafter, transistors 22 and 26 are turned on in a state that transistors 24 and 25 are turned off. When data is read from the fuse element 21, the pre-charged input node of the sense amplifier circuit 23 is discharged to a ground voltage node regardless of the state of the fuse element 21. Therefore, low data is always read from the unit memory circuit of FIG. 5A.

In the unit memory circuit shown in FIG. 5B, the current path of the fuse element 21 is always in an opened state by the interconnect 28. Pre-charge is carried out, and thereafter, transistors 22 and 26 are turned on in a state that transistors 24 and 25 are turned off. When data is read from the fuse element 21, the pre-charged input node of the sense amplifier circuit 23 is not discharged regardless of the state of the fuse element 21. Therefore, high data is always read from the unit memory circuit of FIG. 5B.

The semiconductor memory device of this embodiment has the following advantage. Specifically, if there is a need to set the same data in each chip, it is unnecessary to set data according to a program operation.

### Second Embodiment

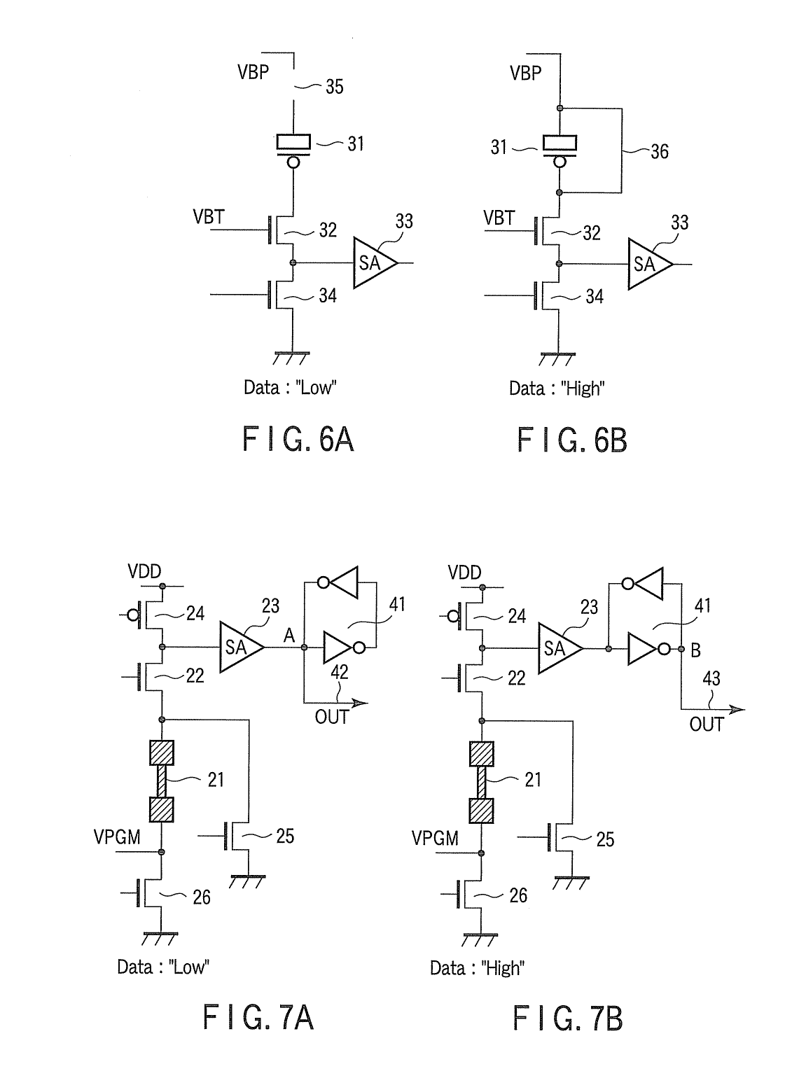

FIGS. 6A and 6B show a semiconductor memory device according to a second embodiment of the present invention. That is, FIGS. 6A and 6B are circuit diagrams showing one configuration example of each unit memory circuit located in the ROM area 12 shown in FIG. 1. In the unit memory circuit, an anti-fuse element using breakdown of a gate oxide film is used as an e-fuse like the unit memory circuit shown in FIG. 4A. The unit memory circuit includes an anti-fuse element 31, NMOS transistors 32, 34 and a sense amplifier circuit (SA) 33 like the circuit shown in FIG. 4A.

If there is a need to set the same data in each chip, in the semiconductor memory device of this embodiment, the anti-fuse element 31 of the unit memory circuit is not electrically programmed, but data is set using the following process. Specifically, as can be seen from the foregoing flowchart shown in FIG. 2, layout data of an interconnect formation mask is corrected based on data to be stored in the mass-production stage. Either of the following interconnects is selectively formed using the foregoing corrected mask. One is an interconnect short-circuiting the anti-fuse element 31. The other is an interconnect cutting off (opening) a current path when data is read from the anti-fuse element 31.

For example, as can be seen from FIG. 6A, a unit memory circuit configured to store low data is formed with an interconnect 35 such that a signal path between a voltage VEP terminal and the anti-fuse element 31 is cut off (opened). As shown in FIG. 6B, a unit memory circuit configured to store high data is formed with an interconnect 36, which short-circuits the anti-fuse element 31. The foregoing interconnect 35 may be formed at a position cutting off (opening) a current path between the anti-fuse element 31 and the transistor 32.

In the unit memory circuit shown in FIG. 6A, the current path of the anti-fuse element 31 is always in an opened state by the interconnect 35. Therefore, low data is always read from the unit memory circuit of FIG. 6A.

In the unit memory circuit shown in FIG. 6B, the anti-fuse element 31 is always short-circuited by the interconnect 36. Therefore, in a read operation, a voltage such as power supply voltage VDD is supplied to a sense node of the sense amplifier circuit 33 regardless of the state of the anti-fuse element 31. In this way, high data is read from the unit memory circuit of FIG. 6B.

The semiconductor memory device of this embodiment has the following advantage. Specifically, if there is a need to set the same data in each chip, it is unnecessary to set data according to a program operation.

### Third Embodiment

FIGS. 7A and 7B show a semiconductor memory device according to a third embodiment of the present invention. That is, FIGS. 7A and 7B are circuit diagrams showing one configuration example of each unit memory circuit located in the ROM area 12 shown in FIG. 1. The unit memory circuit is additionally provided with a latch circuit 41 with respect to the unit memory circuit sown in FIG. 3A. The latch circuit 41 holds a sense output from the sense amplifier circuit 23. In unit memory circuits shown in FIGS. 7A and 7B, a polysilicon fuse element 21, which is fused by carrying a current, is used as an e-fuse such that data is electrically programmed like the circuit shown in FIG. 3A.

If there is a need to set the same data in each chip, in the semiconductor memory device of this embodiment, the fuse element 21 of each unit memory circuit is not electrically programmed, but data is set using the following process. Specifically, as can be seen from the foregoing flowchart shown in FIG. 2, layout data of an interconnect formation mask is corrected based on data to be stored in the mass-production stage. Either of the following interconnects is selectively formed using the foregoing corrected mask. One is an interconnect 42, which reads a sense output of the sense amplifier circuit 23 and outputs it as data. The other is an interconnect 43, which read an output of a latch circuit 41 and outputs it as data.

For example, as can be seen from FIG. 7A, a unit memory circuit configured to store low data is formed with an interconnect 42, which reads a sense output A of the sense amplifier circuit 23 and outputs it as data OUT. As shown in FIG. 7B, a unit memory circuit configured to store high data is formed with an interconnect 43, which reads an output B of the latch circuit 41 and outputs it as data OUT.

In the unit memory circuit shown in FIG. 7A, the sense output A of the sense amplifier circuit 23 is output as read data OUT. The fuse element 21 is not programmed; therefore, it can carry a current. An input node of the sense amplifier circuit 23 is pre-charged by the transistor 24, and thereafter, transistors 22 and 26 are turned on in a state that transistors 24 and 25 are turned off. In this way, data is read from the fuse element 21, and thereby, low data is always read from the sense amplifier circuit 23. Therefore, low data is always read from the unit memory circuit of FIG. 7A.

In the unit memory circuit shown in FIG. 7B, the output B of the latch circuit 41 is output as read data OUT. Inverted data of the data held in the sense amplifier circuit 23, that is, high data is read as a latch output B. Therefore, high data is always read from the unit memory circuit of FIG. 7B.

The third embodiment differs from the first embodiment in the following point. Specifically, both of the interconnect 27 for short-circuiting the fuse element 21 and the interconnect 28 for cutting off a current path when data is read from the fuse element 21 are not formed. Therefore, this serves to program the fuse element 21 even if chips have been manufactured. This configuration can obtain the advantage in the following case. Specifically, the case, that is, if data must be corrected after chips formed with either of interconnects 42 and 43 are manufactured, the fuse element 21 is programmed, and thereby, data is changeable one time only. In the semiconductor memory device of this embodiment, if there is a need to set the same data in ach chip, it is unnecessary to set data according to a program operation. In addition, data is changeable one time only even if chips have been manufactured.

### Fourth Embodiment

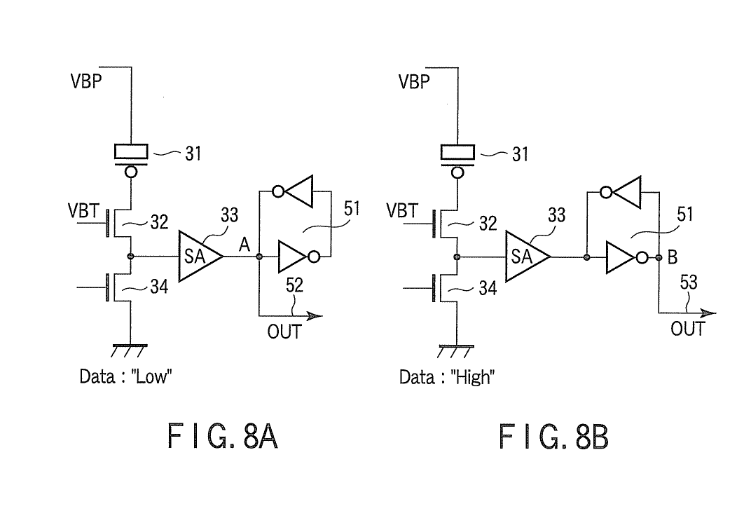

FIGS. 8A and 8B show a semiconductor memory device according to a fourth embodiment of the present invention. That is, FIGS. 8A and 8B are circuit diagrams showing one configuration example of each unit memory circuit located in the ROM area 12 shown in

FIG. 1. The unit memory circuit is additionally provided with a latch circuit 51 with respect to the unit memory circuit sown in FIG. 4A. The latch circuit 51 holds a sense output from the sense amplifier circuit 33. In unit memory circuits shown in FIGS. 8A and 8B, an anti-fuse element, which uses the breakdown of a gate oxide film, is used as an e-fuse such that data is electrically programmed like the circuit shown in FIG. 4A.

If there is a need to set the same data in each chip, in the semiconductor memory device of this embodiment, the anti-fuse element 31 of each unit memory circuit is not electrically programmed, but data is set using the following process. Specifically, as can be seen from the foregoing flowchart shown in FIG. 2, layout data of an interconnect formation mask is corrected based on data to be stored in the mass-production stage. Either of two interconnects described below is selectively formed using the foregoing corrected mask. One is an interconnect 52, which reads a sense output of the sense amplifier circuit 33 and outputs it as data. The other is an interconnect 53, which read an output of the latch circuit 51 and outputs it as data.

In the unit memory circuit shown in FIG. 8A, a sense output A of the sense amplifier circuit 33 is output as read data OUT. The anti-fuse element 31 is not programmed; therefore, it is always in a non-conducted state. Therefore, low data is always read from the sense amplifier circuit 33; in other words, low data is always read from the unit memory circuit of FIG. 8A.

In the unit memory circuit shown in FIG. 8B, an output B of the latch circuit 51 is output as read data OUT. Inverted data of the data held in the sense amplifier circuit 33, that is, high data is read as a latch output B. Therefore, high data is always read from the unit memory circuit of FIG. 8B.

The fourth embodiment differs from the second embodiment in the following point. Specifically, both of the interconnect 36 for short-circuiting the anti-fuse element 31 and the interconnect 35 for cutting off a current path when data is read from the anti-fuse element 31 are not formed. Therefore, this serves to program the anti-fuse element 31 even if chips have been manufactured. This configuration can obtain the advantage in the following case. Specifically, the case, that is, if data must be corrected after chips formed with either of interconnects 52 and 53 are manufactured, the anti-fuse element 31 is programmed, and thereby, data is changeable one time only.

In the semiconductor memory device of this embodiment, if there is a need to set the same data in each chip, it is unnecessary to set data according to a program operation. In addition, data is changeable one time only even if chips have been manufactured.

Namely, the summary of the present invention is as follows.

A first semiconductor memory device is configured according to the first and second embodiments. The first semiconductor memory device comprises: a fuse element capable of electrically programming data; a sense amplifier circuit sensing the data of the fuse element; and either of a first interconnect shot-circuiting the fuse element and a second interconnect cutting off a current path when data is read from the fuse element.

A second semiconductor memory device is configured according to the third and fourth embodiments. The second semiconductor memory device comprises: an anti-fuse element capable of electrically programming data; a sense amplifier circuit sensing the data of the anti-fuse element; a latch circuit having an inversion function of latching a sense output of the sense amplifier circuit; and either of a first interconnect outputting a sense output of the sense amplifier circuit as read data and a second interconnect outputting an output of the latch circuit as read data.

In a third semiconductor memory device, a ROM area is provided with a plurality of unit memory circuits corresponding to the first and second embodiments. On the other hand, a field program area is provided with a plurality of unit memory circuit including a fuse element capable of electrically programming data and a sense amplifier circuit sensing the data of the fuse element.

In a fourth semiconductor memory device, a ROM area is provided with a plurality of unit memory circuits corresponding to the third and fourth embodiments. On the other hand, a field program area is provided with a plurality of unit memory circuit including a fuse element capable of electrically programming data and a sense amplifier circuit sensing the data of the fuse element.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

The foregoing first to fourth embodiments show the case where the same kind of unit memory circuits shown in FIGS. 5 to 8 are located in the ROM area 12. For example, the following configuration may be employed. Specifically, the different kind of unit memory circuits shown in FIGS. 5 and 7 may be located in the ROM area 12. Moreover, the different kind of unit memory circuits shown in FIGS. 6 and 8 may be located in the foregoing ROM area 12.

What is claimed is:

1. A semiconductor memory device comprising:
a fuse element capable of electrically programming data;
a sense amplifier circuit connected to the fuse element to sense data of the fuse element; and
either of a first interconnect selectively formed by changing an interconnect formation mask, and short-circuiting the fuse element and a second interconnect cutting off a current path when data is read from the fuse element.

2. The device according to claim 1, further comprising:
a first switch element connected between the fuse element and an input node of the sense amplifier circuit; and
a second switch element connected between the input node of the sense amplifier circuit and either of a power supply voltage node and a reference voltage node, and being complementarily controlled in its conduction with respect to the first switch element.

3. The device according to claim 1, wherein the fuse element being fused by carrying a current to electrically insulate.

4. The device according to claim 1, wherein the fuse element is an anti-fuse element, which is conducted by applying an electric field to a gate oxide film of a transistor, the gate oxide film being broken down.

5. A semiconductor memory device comprising:
a fuse element capable of electrically programming data;
a sense amplifier circuit connected to the fuse element to sense data programmed in the fuse element;
a latch circuit connected to the sense amplifier circuit, and including an inversion function of holding a sense output of the sense amplifier circuit; and
either of a first interconnect selectively formed by changing an interconnect formation mask and outputting the sense output of the sense amplifier circuit as read data and a second interconnect outputting an output of the latch circuit as read data.

6. The device according to claim 5, further comprising:
a first switch element connected between the fuse element and an input node of the sense amplifier circuit; and
a second switch element connected between the input node of the sense amplifier circuit and either of a power supply voltage node and a reference voltage node, and being complementarily controlled in its conduction with respect to the first switch element.

7. The device according to claim 5, wherein the fuse element being fused by carrying a current to electrically insulate.

8. The device according to claim 5, wherein the fuse element is an anti-fuse element, which is conducted by applying an electric field to a gate oxide film of a transistor, the gate oxide film being broken down.

9. A semiconductor memory device comprising:
a first area including a plurality of first unit memory circuits, each of the first unit memory circuit comprising: a first fuse element capable of electrically programming data; and a first sense amplifier circuit connected to the first fuse element and sensing data programmed in the first fuse element; and
a second area including a plurality of second unit memory circuits, each of the second unit memory circuit comprising: a second fuse element capable of electrically programming data; a second sense amplifier circuit connected to the second fuse element and sensing data programmed in the second fuse element; and either of first and second interconnects selectively formed by changing an interconnect formation mask and setting memory data regardless of a program state of the second fuse element.

10. The device according to claim 9, wherein the first interconnect short-circuits both terminals of the second fuse element, and the second interconnect cuts off a current path when data is read from the second fuse element.

11. The device according to claim 9, further comprising:
a first switch element connected between the first fuse element and an input node of the first sense amplifier circuit;
a second switch element connected between the input node of the first sense amplifier circuit and either of a power supply voltage node and a reference voltage node, and being complementarily controlled in its conduction with respect to the first switch element;
a third switch element connected between the second fuse element and an input node of the second sense amplifier circuit; and
a fourth switch element connected between the input node of the second sense amplifier circuit and either of a power supply voltage node and a reference voltage node, and being complementarily controlled in its conduction with respect to the third switch element.

12. The device according to claim 9, wherein each of the first unit memory circuits further includes a first latch circuit, which is connected to the first sense amplifier circuit and includes an inversion function of holding an sense output of the first sense amplifier circuit,
each of the second unit memory circuits further includes a second latch circuit, which is connected to the second sense amplifier circuit and includes an inversion function of holding an sense output of the second sense amplifier circuit, and
the first interconnect outputs a sense output of the second sense amplifier circuit as read data while the second interconnect outputs an output of the second latch circuit as read data.

13. The device according to claim 9, wherein the fuse element being fused by carrying a current to electrically insulate.

14. The device according to claim 9, wherein the fuse element is an anti-fuse element, which is conducted by applying an electric field to a gate oxide film of a transistor, the gate oxide film being broken down.
